(19) United States
(12) Patent Application Publication
(10) Pub. No.: US 2003/0034500 A1
(43) Pub. Date: Feb. 20, 2003

(54) Semiconductor structure including a zintl material buffer layer, device including the structure, and method of forming the structure and device

(75) Inventors: Alexander A. Demkov, Phoenix, AZ (US); Zhiyi Yu, Gilbert, AZ (US); Jamal Ramdani, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/929,018

(22) Filed: Aug. 15, 2001

(51) Int. Cl. H01L 29/74

(52) U.S. Cl. 257/120

(57) ABSTRACT

High quality epitaxial layers of monocrystalline materials (106) can be grown overlying monocrystalline substrates (102) such as large silicon wafers by forming a compliant substrate for growing the monocrystalline layers. One way to achieve the formation of a compliant substrate includes first growing an accommodating Zintl buffer layer (104) on a silicon wafer. Any lattice mismatch between the monocrystalline layer (106) and the underlying silicon substrate (102) is absorbed by the Zintl interface layer (104).

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer formed overlying a Zintl material buffer layer.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of the material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer epitaxially formed over another monocrystalline material, having a different lattice constant than the lattice constant of the grown film, and for a process for making such a structure.

### BRIEF DESCRIPTION OF THE DRAWINGS

The present invention is illustrated by way of example and not limitation in the accompanying figures, in which like references indicate similar elements, and in which:

FIG. 1 illustrates schematically, in cross section, a device structure in accordance with various embodiments of the invention;

FIG. 2 illustrates schematically, in cross section, a portion of the device structure of FIG. 1 in greater detail.

FIG. 3 illustrates graphically the relationship between maximum attainable film thickness and lattice mismatch between a host crystal and a grown crystalline overlayer, absent a buffer layer; and

FIGS. 4 and 5 illustrate schematically, in cross section, device structures that can be used in accordance with various embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 100 in accordance with an embodiment of the invention. Semiconductor structure 100 includes a monocrystalline substrate 102, a Zintl buffer layer 104, and a monocrystalline material layer 106. Structure 100 may also include a template layer 108 configured to facilitate monocrystalline growth of layer 106. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

Substrate 102, in accordance with an embodiment of the invention, is a monocrystalline semiconductor or compound semiconductor wafer, preferably of large diameter. The wafer can be of, for example, a material from Group IV of the periodic table, and preferably a material from Group IVB, e.g., Carbon, Silicon, etc. Examples of Group IV semiconductor materials include silicon, germanium, mixed silicon and germanium, mixed silicon and carbon, mixed silicon, germanium and carbon, and the like. Preferably substrate 102 is a wafer containing silicon or germanium, and most preferably is a high quality monocrystalline silicon wafer as used in the semiconductor industry.

Zintl buffer layer 104 comprises an intermetallic material which includes a material formed of at least two elements: one which is relatively electronegative and one that is relatively electropositive. By way of example, the electropositive material may be selected from elements listed in Group I (e.g., Na, K, Rb, Cs) or Group II (e.g., Ca, Sr, Ba) of the Periodic Table and the electronegative material may be selected from elements listed in Group III of the Periodic Table (e.g., Al). The combination of the electronegative and electropositive materials form a Zintl phase material which includes relatively elastic valance bonds between adjacent electronegative elements. The formation of the valance bonds between elements allows the Zintl phase material to absorb a relatively large amount of strain without breaking bonds of the material. Thus, the Zintl buffer layer can be used to form a transition layer between a substrate having a lattice constant and a subsequently formed layer of monocrystalline material having a different lattice constant. As used herein, lattice constant refers to the distance between atoms of a unit cell measured in the plane of the surface. If strain resulting from lattice mismatch is not relieved by the Zintl interface layer, the strain may cause defects in the crystalline structure of layer 106.

The material for monocrystalline material layer 106 can be selected, as desired, for a particular structure or application. For example, the monocrystalline material of layer 106 may comprise a compound semiconductor which can be selected, as needed for a particular semiconductor structure, from any of the Group IIIB and VB elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), germanium (Ge) and the like. Monocrystalline material layer 106 may also comprise other semiconductor materials, metals, or non-metal materials which are used in the formation of semiconductor structures, devices and/or integrated circuits. Furthermore, semiconductor structures in accordance with the present invention may include multiple layers of monocrystalline material formed overlying substrate 102, as described herein.

Appropriate materials for template 108 are discussed below. Suitable template materials chemically bond to the surface of Zintl buffer layer 104 at selected sites and provide sites for the nucleation of the epitaxial growth of monocrystalline material layer 106. When used, template layer 108 has a thickness ranging from about 1 to about 10 mono layers.

FIG. 2 illustrates a portion 200 of structure 100 in greater detail, showing a top surface of substrate 102, Zintl layer 104, and template layer 108. As noted above, Zintl layer 104 includes relatively electropositive atoms 202 and relatively electronegative atoms 204 bonded to the electropositive atoms. The electropositive atoms bond to the silicon surface at selected sites and provide an ordered 2×1 surface for subsequent film deposition. The thickness of the film formed of electropositive atoms is thick enough to provide a suitable template for subsequent monocrystalline growth and thin enough to prevent or mitigate undesired silicide formation (when substrate 102 comprises silicon). If the layer of electropositive atoms is greater than about two monolayers, undesired silicide formation may result. Preferred compositions of layer 104 are strontium aluminides such as SrAl₂ and SrAl₄. In these cases, either about two or about four atoms of aluminum are deposited onto the about one half to about two monolayers of strontium atoms. Although illustrated as a single layer of SrAlₓ, buffer layer 104 may include a plurality of alternating layers of electropositive and electronegative elements, wherein the electropositive portion of each layer is about one half to about two monolayers thick and the electronegative portion is thick enough to form the desired material composition.

Zintl template layer 104 can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Template layer 108 includes a relatively electropositive material 208, which bonds to the electronegative portion of Zintl buffer layer 104. For example, template 108 may include Group V materials such as arsenic, which bond to a portion of the Zintl buffer layer to form a template suitable for Group III-V (e.g., GaAs) or group IV (e.g., Ge) monocrystalline material layers.

The following non-limiting, illustrative examples illustrate various combinations of materials useful in structure 100 in accordance with various alternative embodiments of the invention. These examples are merely illustrative, and it is not intended that the invention be limited to these illustrative examples.

### EXAMPLE 1

In accordance with one embodiment of the invention, monocrystalline substrate 102 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, Zinti buffer layer is a layer of SrAl₂, having a strontium thickness of about one half to about two monolayers. Monocrystalline material layer 106 is a compound semiconductor layer of gallium arsenide or aluminum gallium arsenide having a thickness of about 1 nm to about 100 micrometers (μm) and preferably a thickness of about 0.5 82 m to 10 μm. The thickness generally depends on the application for which the layer is being prepared. Layer 108 is formed of about 1 nm to about 10 nm of AlAs.

### EXAMPLE 2

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable Zintl buffer layer material is AlₓSr where x ranges from about 2 to about 4, having a thickness of about 2-100 nm and preferably a thickness of about 5-15 nm. The II-VI compound semiconductor material can be, for example, zinc selenide (ZnSe) or zinc sulfur selenide (ZnSSe).

Referring again to FIGS. 1-2, substrate 102 is a monocrystalline substrate such as a monocrystalline silicon substrate. The crystalline structure of the monocrystalline substrate is characterized by a lattice constant and by a lattice orientation. In similar manner, monocrystalline material layer 106 is also a monocrystalline material and the lattice of that monocrystalline material is characterized by a lattice constant and a crystal orientation. Without the inclusion of Zintl buffer layer 104, the lattice constants of the monocrystalline material layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

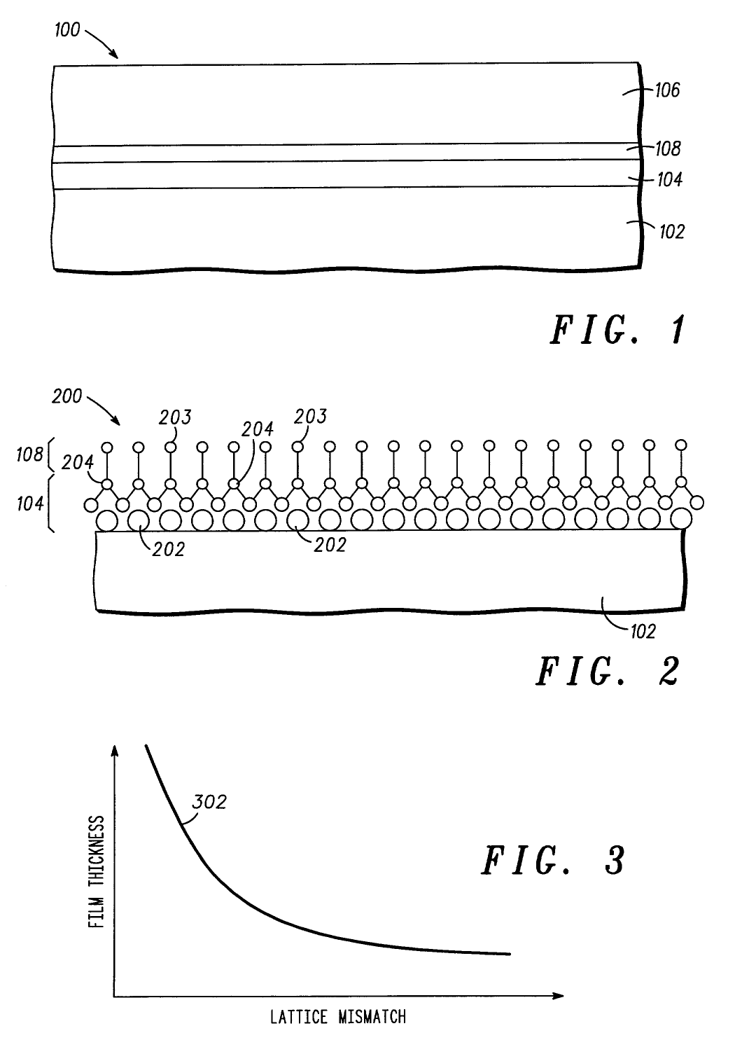

FIG. 3 illustrates graphically the relationship of the achievable thickness of a grown crystal layer of high crystalline quality as a function of the mismatch between the lattice constants of the host crystal and the grown crystal. Curve 302 illustrates the boundary of high crystalline quality material. The area to the right of curve 302 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved. The inclusion of Zintl layer 104 allows greater mismatch between the host crystal and the subsequently formed layer of monocrystalline material because it absorbs stress resulting from any lattice mismatch between the host and the grown crystal. Thus, thicker films of monocrystalline material, for a given lattice mismatch, can be grown on an underlying substrate, without significant defect formation in the grown layer.

The following example illustrates a process, in accordance with one embodiment of the invention, for fabricating a semiconductor structure such as the structure depicted in FIG. 1. The process starts by providing a monocrystalline semiconductor substrate comprising silicon. In accordance with a preferred embodiment of the invention, the semiconductor substrate is a silicon wafer having a (100) orientation. The substrate is preferably oriented on axis or, at most, about 40° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. In order to epitaxially grow a monocrystalline Zintl layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium and silicon. The ordered 2×1 structure forms a template for the ordered growth of an overlying layer of a monocrystalline Zintl material. The template provides the necessary chemical and physical properties to nucleate the crystalline growth of an overlying layer.

In accordance with an alternate embodiment of the invention, the native silicon oxide can be removed using flash techniques. For example, the silicon oxide can be exposed to a hydrogen environment at an elevated temperature to remove the oxide from the surface of the silicon wafer. Following the removal of the silicon oxide from the surface of the substrate, in accordance with one embodiment of the invention, the substrate is cooled to a temperature in the range of about 200-800° C. and a layer of strontium is deposited onto the silicon surface via molecular beam epitaxy. The MBE process is initiated by opening shutters in the MBE apparatus to expose a strontium source.

After the strontium portion is grown to the desired thickness (about one half to about two monolayers), aluminum is deposited onto the strontium/silicon surface to form a Zintl layer of strontium alumindide—e.g., SrAl₂ or SrAl₄. As noted above, this buffer layer formation step may be repeated as desired to form a Zintl buffer layer of a desired thickness. For example, the buffer layer may include 2-5 layers of SrAl₂, wherein each layer is formed by first depositing about one half to about two monolayers of strontium followed by depositing aluminum to form SrAl₂.

Once the buffer layer is grown to a desired thickness by forming a desired number of SrAl₂ layers, a template layer is formed by exposing the Zintl layer to an arsenic source to form an AlAs template layer. Following the formation of the template, gallium is subsequently introduced and gallium arsenide forms.

The process described above illustrates a process for forming a semiconductor structure including a silicon substrate, a Zintl accommodating layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

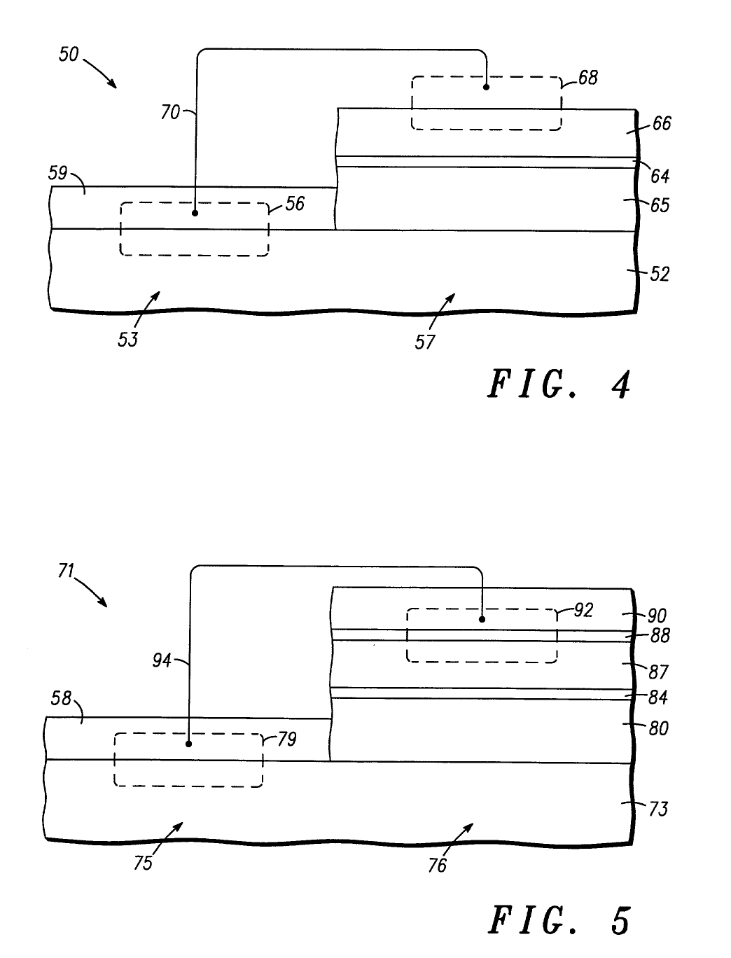

FIG. 4 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 54. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 58 such as a layer of silicon dioxide or the like may overlie electrical semiconductor component 56.

Insulating material 58 and any other layers that may have been formed or deposited during the processing of semiconductor component 56 in region 53 are removed from the surface of region 54 to provide a bare silicon surface in that region. As is well known, bare silicon surfaces are highly reactive and a native silicon oxide layer can quickly form on the bare surface. Next, a Zintl material layer (e.g., SrAl₂) is formed overlying the silicon substrate as described above.

An AlAs template layer 64 is then formed and a layer 66 of a monocrystalline compound semiconductor material is then deposited overlying template layer 64 by a process of molecular beam epitaxy. The deposition of layer 66 is initiated by depositing a layer of gallium onto template 64. This initial step is followed by depositing arsenic and gallium to form monocrystalline gallium arsenide layer 66.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a gallium arsenide layer 66, similar devices can be fabricated using other substrates and other compound semiconductor layers as described elsewhere in this disclosure.

FIG. 5 illustrates a semiconductor structure 72 in accordance with a further embodiment. Structure 72 includes a monocrystalline semiconductor substrate 74 such as a monocrystalline silicon wafer that includes a region 75 and a region 76. An electrical component schematically illustrated by the dashed line 78 is formed in region 75 using conventional silicon device processing techniques commonly used in the semiconductor industry. Using process steps similar to those described above, Zintl layer 80 is formed overlying region 76 of substrate 74. A template layer 84 and subsequently a monocrystalline semiconductor layer 86 are formed overlying Zintl material layer 80. In accordance with a further embodiment, an additional monocrystalline oxide layer 88 is formed overlying layer 86 by an epitaxial process, and an additional monocrystalline semiconductor layer 90 is formed overlying monocrystalline oxide layer 88 by process steps similar to those used to form layer 86. In accordance with one embodiment, at least one of layers 86 and 90 are formed from a compound semiconductor material.

A semiconductor component generally indicated by a dashed line 92 is formed at least partially in monocrystalline semiconductor layer 86. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 86 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 78 and component 92. Structure 72 thus integrates components that take advantage of the unique properties of the two monocrystalline semiconductor materials.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline silicon substrate;
a Zintl material overlying and in contact with at least a portion of the monocrystalline silicon substrate; and
a monocrystalline compound semiconductor material overlying the Zintl material.

2. The semiconductor structure of claim 1, wherein the Zintl material comprises an alkaline earth metal.

3. The semiconductor structure of claim 2, wherein the alkaline earth metal comprises strontium.

4. The semiconductor structure of claim 3, wherein strontium is about one half to about 2 monolayers thick.

5. The semiconductor structure of claim 1, wherein the Zintl material comprises a Group III metal.

6. The semiconductor structure of claim 5, wherein the Group III metal comprises aluminum.

7. The semiconductor structure of claim 1, wherein the Zintl material comprises strontium aluminide.

8. The semiconductor structure of claim 1, wherein the Zintl material comprises a plurality of layers, each of the plurality of layers comprising an electropositive element and an electronegative element.

9. The semiconductor structure of claim 1, wherein the monocrystalline compound semiconductor material comprises GaAs.

10. The semiconductor structure of claim 1, further comprising a first electronic device formed using the monocrystalline compound semiconductor material.

11. The semiconductor structure of claim 10, firther comprising a second electronic device formed using the monocrystalline silicon substrate, the second electronic device coupled to the first electronic device.

12. A process for fabricating a semiconductor structure comprising:
providing a monocrystalline silicon substrate;
depositing a Zintl buffer layer material overlying and in contact with at least a portion of the monocrystalline silicon substrate; and
epitaxially forming a monocrystalline compound semiconductor layer overlying the monocrystalline perovskite oxide film.

13. The process of claim 12, further comprising the step of removing silicon oxide from the surface of the monocrystalline silicon substrate.

14. The process of claim 13, wherein the step of depositing a Zintl buffer layer material comprises:
depositing about one half to about two monolayers of strontium onto the surface of the monocrystalline silicon substrate; and
depositing aluminum onto the strontium to form AlₓSr, where x ranges from about 2 to about 4.

15. The process of claim 12, wherein the step of depositing a Zintl buffer layer material comprises forming a layer of strontium aluminide.

16. The process of claim 12, wherein the step of epitaxially forming a monocrystalline compound semiconductor layer comprises growing a layer of GaAs.

17. The process of claim 12, further comprising the step of exposing the Zintl buffer layer material to a Group V material to form a template for subsequent monocrystalline material growth.

18. The process of claim 12, further comprising the step of forming an electronic device using the monocrystalline compound semiconductor layer.

19. The process of claim 12, further comprising the step of forming an electronic device using the monocrystalline silicon substrate.

20. The process of claim 12, further comprising the step of forming a plurality of layers of Zintl buffer layer material.

21. A semiconductor structure comprising:
a monocrystalline silicon substrate;
a Zintl material comprising strontium and aluminum overlying and in contact with at least a portion of the monocrystalline silicon substrate; and
a monocrystalline GaAs layer overlying the Zintl material.
